(19) United States
(12) Patent Application Publication
(10) Pub. No.: US 2017/0123509 A1
(43) Pub. Date: May 4, 2017

(54) USER INPUT SYSTEM AND METHOD COMPRISING AN INTERCHANGEABLE GRAPHIC MODULE HAVING GRAPHICAL MARKINGS

(71) Applicant: A.C. DISPENSING EQUIPMENT INC., Lower Sackville (CA)

(72) Inventors: Greg ERMAN, Head of Chezzetcook (CA); Derek COLE, Lower Sackville (CA); Slaven STARCEVIC, Halifax (CA); Andrew DARROW, Lower Sackville (CA); Kevin STONEMAN, Lower Sackville (CA); Brian GAY, Enfield (CA); Ian MACLEAN, Fall River (CA)

(21) Appl. No.: 15/072,799

(22) Filed: Mar. 17, 2016

Related U.S. Application Data
(60) Provisional application No. 62/248,801, filed on Oct. 30, 2015.

(51) Int. Cl. G06F 3/023; H03K 17/96; G06F 3/0484

(52) U.S. Cl. CPC G06F 3/0238; G06F 3/04842; H03K 17/9618

(57) ABSTRACT

The present disclosure is directed to a user input system and method for receiving and processing touch input. The system may cooperate with an interchangeable graphic module that may be received in an overlapping relationship to a touch sensor panel of the system. The interchangeable graphic module may have a graphical layout having one or more graphical elements visually marked on the interchangeable graphic module. A user may view the graphical elements and provide touch input to the touch sensor panel. The user input system may be configured by obtaining a graphic code associated with the interchangeable graphic module identifying the particular graphical layout. The system may configure soft-keys for the touch sensor panel corresponding to the graphical elements. Therefore embodiments of the user input system may provide a configurable touch input system presenting graphical elements without requiring an electronic display.

### CROSS-REFERENCE TO RELATED APPLICATION

This application claims the benefit of priority of U.S. Provisional Patent Application No. 62/248,801 filed Oct. 30, 2015, which is incorporated herein by reference.

### FIELD

The present disclosure relates generally to systems for receiving and processing user touch input.

### BACKGROUND

User input devices are used in various applications to provide an interface between a physical action from a user and a machine for doing work. Generally, a user input device receives a physical user input and translates the user input into information that can be used by the machine. In the case of an electronic machine or computer, the input device may process the user input and generate an analog or digital signal.

An input device such as a mechanical switch or button translates a physical motion into an electrical signal. These mechanical inputs, however, are typically fixed to the machine and are not re-configurable in their function.

Recently, machines have incorporated more complex input systems such as touchscreens. Touchscreens comprise a visual display, such as a liquid crystal display (LCD) display panel, and a sensor matrix layered over the visual display. The sensor matrix may be, for example, a resistive input panel or a capacitive input panel. The visual display and the sensor matrix can each be programmed to cooperate with each other so that the sensor matrix can be sensitive at specific locations corresponding to graphical elements displayed on the visual display. By programming the touchscreen input device, more flexibility may be provided to the machine. Specifically, the machine can be configured to perform different tasks or operate in different modes depending on the programming of the touchscreen input device.

FIG. 1 shows an example machine having a touchscreen input. The machine 10 is a fluid dispensing machine, or “dispenser”. The dispenser 10 includes a door 12 for accessing internal components of the dispenser. The outside front face of the door houses a touchscreen input 14. The touchscreen input 14 is programmable to provide the dispenser 10 with different functions.

For example, the dispenser 10 may include a liquid cartridge 16 containing coffee. This first configuration of the dispenser is used for making a certain type of beverage. The touchscreen input 14 may be programmed to display a “dispense coffee” button or icon on the visual display and to configure the sensor panel to detect a touch input on the portion of the sensor panel directly superimposed over the button graphic on the visual display. Configuring the touchscreen input 14 in this way is often known as programming a “soft-button” or “soft-key”.

In a different commercial application, the dispenser 10 is used for making a different type of beverage so the liquid cartridge 16 contains tea. Therefore, the touchscreen input 14 may be re-programmed to provide a different soft-key and display a different graphic showing “dispense tea” text.

Furthermore, the dispenser 10 may be used for making either beverages including both coffee and tea. In this case, the touchscreen input 14 may be programmed to provide two soft-keys rather than only a single soft-key.

Although a touchscreen input is a powerful tool that can be used in the scenarios above to provide more flexibility to a machine, such as the dispenser 10, the touchscreen increases the cost, power consumption, and overall complexity of the machine in which the touchscreen is used.

It is, therefore, desirable to provide a machine with a user input system that is low-cost to manufacture, has low power consumption, and which is less complex and susceptible to failure than a touchscreen, yet still provides the machine with flexible soft-key functionality.

### BRIEF DESCRIPTION OF THE DRAWINGS

Embodiments of the present disclosure will now be described, by way of example only, with reference to the attached Figures.

FIG. 1 is a diagram of a fluid dispensing machine known in the art;

FIG. 2A is a block diagram of a user input system according to an embodiment of the present disclosure showing interchangeable graphic module in a disengaged position;

FIG. 2B is a block diagram of the user input system of FIG. 2A showing the interchangeable graphic module in an engaged position;

FIGS. 3A-3D are example variations of an interchangeable graphic according to embodiments of the present disclosure;

FIG. 4 is a flow chart showing steps of a method according to an embodiment of the present disclosure;

FIG. 5 is a perspective view of the front of a user input system according to an embodiment of the present disclosure;

FIG. 6 is a rear perspective view of the input system of FIG. 5 with a back panel removed;

FIG. 7 is a cross-sectional side view of the input system of FIG. 5;

FIG. 8 is an exploded view of the input system of FIG. 5; and

FIG. 9 is a block diagram of an example electronic device that may be used in implementing one or more aspects or components of an embodiment according to the present disclosure.

### DETAILED DESCRIPTION

According to one aspect, the present disclosure is directed to a method for configuring a user input system, the method comprising receiving a code at a code input device of the user input system, the code associated with a graphical layout of an interchangeable graphic module releasably engaged with the user input system, and the graphical layout comprising a graphical element visually marked on the interchangeable graphic module and corresponding to a machine function, automatically configuring by a processor of the user input system, based on the graphical layout associated with the received code, a soft-key for a touch sensor device corresponding to the graphical element, and mapping the soft-key to the machine function corresponding to the graphical element.

In some embodiments, the automatically configuring and mapping the soft-key is based on configuration information associated with the received code, and the configuration information comprising information indicating at least one of: a location, a shape, or a size of the graphical element, or a machine function associated with the graphical element.

In some embodiments, the method further comprises retrieving at least part of the configuration information from a memory of the user input system.

In some embodiments, the method further comprises obtaining at least part of the configuration information from the interchangeable graphic module.

In some embodiments, the method further comprises receiving, at the user input system, computer readable instructions associated with the code from the interchangeable graphic module, wherein at least one of the automatically configuring the soft-key and the mapping the soft-key involves executing the received computer readable instructions by the processor of the user input system.

In some embodiments, the receiving the code comprises receiving the code from the interchangeable graphic module over a wireless radio frequency signal.

In some embodiments, the receiving the code comprises reading a graphical representation of the code from the interchangeable graphic module using an optical scanning device of the code input device.

In some embodiments, the configuring and mapping the soft-key is performed automatically in response to the user input system being powered up and the interchangeable graphic module being engaged with the user input system.

In some embodiments, the method further comprises receiving input at the soft-key of the touch sensor device, and generating a machine function output signal in response to the received input, the machine function output signal corresponding to the machine function that corresponds to the graphical element.

In some embodiments, the graphical layout of the interchangeable graphic module further comprises a second graphical element visually marked on the interchangeable graphic module and corresponding to a second machine function, and the method further comprises automatically configuring by the processor, based on the graphical layout associated with the received code, a second soft-key for the touch sensor device corresponding to the second graphical element, mapping the second soft-key to the second machine function corresponding to the second graphical element, receiving a first input at the soft-key, receiving a second input at the second soft-key, generating a machine function output signal in response to the received first and second inputs, the machine function output signal corresponding to the two machine functions of the two graphical elements.

In some embodiments, the interchangeable graphic module is positioned in an overlapping relationship with the touch sensor device when the interchangeable graphic module is engaged with the user input system.

According to another aspect, the present disclosure is directed to a user input system comprising an interface for receiving an interchangeable graphic module having a code associated with a graphical layout of the module, the graphical layout comprising a graphical element visually marked on the interchangeable graphic module and corresponding to a machine function, a touch sensor device, a code input device, and a processor in communication with the touch sensor device and the code input device, the processor configured to receive, via the code input device, the code associated with the graphical layout of the interchangeable graphic module, configure, based on the graphical layout associated with the received code, a soft-key for the touch sensor device corresponding to the graphical element, and map the soft-key to the machine function corresponding to the graphical element.

In some embodiments, the processor is configured to configure the soft-key and map the soft-key based on configuration information associated with the received code, the configuration information comprising information indicating at least one of: a location, a shape, or a size of the graphical element, or a machine function associated with the graphical element.

In some embodiments, the user input system further comprises a memory, wherein the processor is configured to retrieve at least part of the configuration information from the memory.

In some embodiments, the processor is configured to obtain at least part of the configuration information from the interchangeable graphic module.

In some embodiments, the user input system is further configured to receive computer readable instructions associated with the code from the interchangeable graphic module, wherein the processor is further configured to at least one of configure the soft-key and map the soft-key based on the execution of the received computer readable instructions by the processor.

In some embodiments, the code input device comprises a wireless interface device, and wherein the user input system is configured to receive the code from the interchangeable graphic module over a wireless radio frequency signal using the wireless interface device.

In some embodiments, the code input device comprises an optical scanning device configured to read a graphical representation of the code from the interchangeable graphic module.

In some embodiments, the processor is configured to configure and map the soft-key automatically in response to the user input system being powered up and the interchangeable graphic module being engaged with the user input system.

In some embodiments, the user input system is further configured to receive input at the soft-key of the touch sensor device, and generate a machine function output signal in response to the received input, the machine function output signal corresponding to the machine function of the graphical element.

In some embodiments, when the graphical layout of the interchangeable graphic module further comprises a second graphical element visually marked on the interchangeable graphic module and corresponding to a second machine function, the processor is further configured to configure a second soft-key for the touch sensor device corresponding to the second graphical element, and map the second soft-key to the second machine function, and wherein the user input system is further configured to receive a first input at the soft-key, receive a second input at the second soft-key, and generate a machine function output signal in response to the received first and second inputs, the machine function output signal corresponding to the two machine functions of the two graphical elements.

In some embodiments, the interchangeable graphic module is receivable by the interface in an overlapping relationship with the touch sensor device.

In some embodiments, the touch sensor device comprises a transparent sensor panel, and wherein the interchangeable graphic module is receivable by the interface behind the transparent panel such that the graphical layout is viewable through the transparent sensor panel.

In some embodiments, the user input system further comprises the interchangeable graphic module.

Generally, the present disclosure is directed to a user input system and method comprising an interchangeable graphic module, which comprises a graphical layout having one or more graphical elements visually marked on the interchangeable graphic module. In some embodiments, the interchangeable graphic module may be in the form of a cardboard or plastic card. The graphic module is interchangeable in the sense that a first module may be removed from the input system and replaced with a different second module. The interchangeable graphic module may comprise or be associated with a unique graphic code, which may be used by the user input system to identify or determine configuration information for the interchangeable graphic module. The configuration information may include the particular graphical layout visually marked on the module, such as one or more of the size, location, and function of buttons represented by graphical elements visually marked on the interchangeable graphic module. In an embodiment, configuration information may be stored on the interchangeable graphic module. The input system has a code input device for receiving the unique graphic code and has a processor for configuring one or more soft-keys of a touch sensor device according to the graphical layout associated with the received graphic code. The processor may also map functions to each soft-key. According to embodiments of the present disclosure, a user input system provides programmable soft-keys without the cost and complexity of a conventional touchscreen input device. Therefore embodiments of the user input system may provide a configurable touch input system presenting graphical elements without requiring an electronic display.

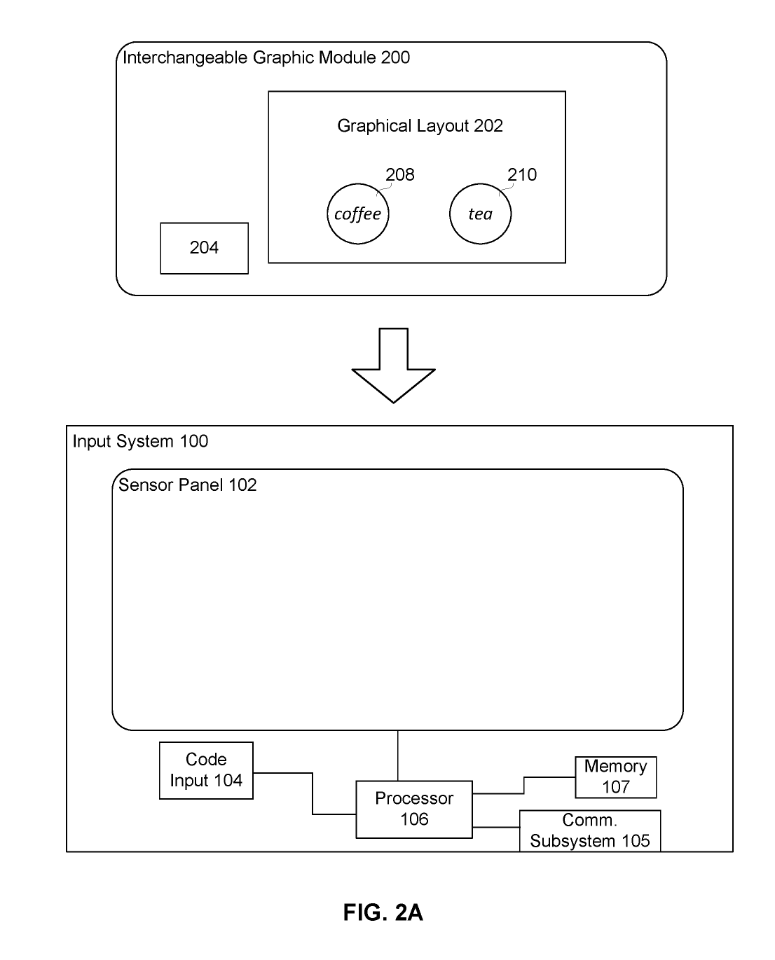

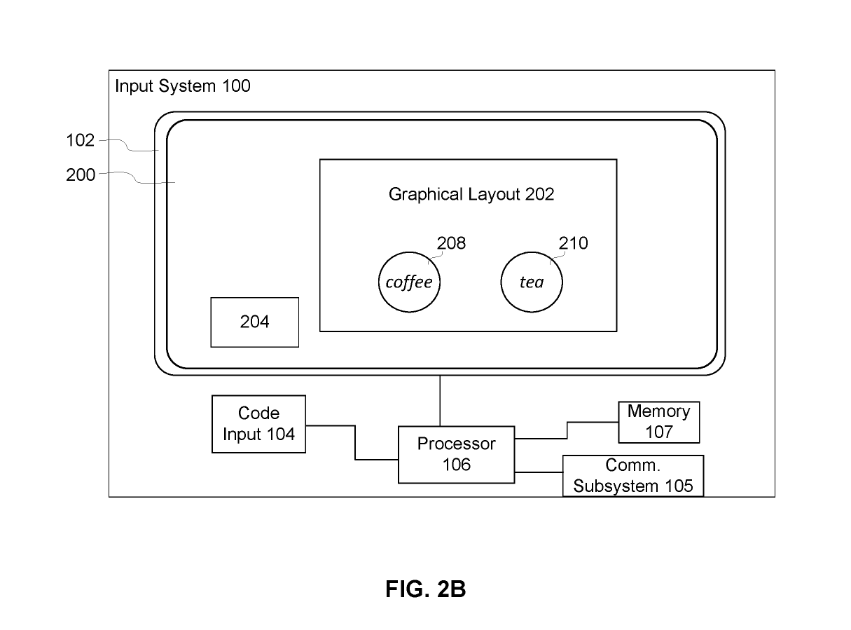

FIG. 2A is a block diagram of user input system 100 according to an embodiment of the present disclosure. The user input system 100 comprises a touch sensor device 102, which may be in the form of a sensor panel, a code input device 104, and a processor 106. User input system 100 may further comprise a communications subsystem 105 for performing input and/or output, and memory 107. In operation, the user input system 100 may comprise or cooperate with interchangeable graphic module 200, which may releasably engage a module interface of the user input system 100. For example, in one embodiment, module 200 may be received into a slot defined by system 100. FIG. 2A shows an interchangeable graphic module 200 in a disengaged position. In contrast, FIG. 2B shows the interchangeable graphic module 200 engaged with the user input system 100.

In the engaged position, the interchangeable graphic module 200 may be suitably oriented relative to touch sensor device 102. The interchangeable graphic module 200 and touch sensor device 102 may cooperate to provide soft-key functionality to the user input system 100.

The interchangeable graphic module 200 comprises graphical layout 202 and graphic code 204. The graphic code 204 may be associated with the graphical layout 202 visually marked on the interchangeable graphic module 200, and may provide the input system 100 with configuration information about the graphical layout 202 on the interchangeable graphic module 200.

In an embodiment, the input system 100 may be used in combination with one of several different variations of interchangeable graphic module 200. A variation of an interchangeable graphic module 200 generally refers to a module having a particular graphical layout 202, and therefore a different associated graphic code 204 as well. The different graphical layouts 202 may be, for example, different layouts of button graphics and/or text. FIGS. 2A and 2B show an example graphical layout 202 having two graphical elements 208, 210 visually marked on the interchangeable graphic module. In one embodiment, the different layouts may include text for different fluids such as coffee and tea, and different numbers of buttons.

An interchangeable graphic module 200 may be separately receivable in or on user input system 100 in a releasably engagement fashion. By engaging a particular variation of an interchangeable graphic module 200 with the user input system 100, the input system 100 may be automatically configured for receiving and processing user input based on the particular graphical layout 202 of the interchangeable graphic module 200. The term automatically generally means that no human intervention is involved.

In use, the interchangeable graphic module 200 may be received by or otherwise engaged with user input system 100 such that interchangeable graphic module 200 is positioned in an overlapping relationship to the touch sensor device 102. In some embodiments, touch sensor device 102 may be positioned outwardly of interchangeable graphic module 200 such that user input directly contacts touch sensor device 102. In such embodiments, touch sensor device 102 may comprise a transparent region to allow for the viewing of the graphical layout 202 on the interchangeable graphic module 200 through the touch sensor device 200. In other embodiments, touch sensor device 102 may be positioned inwardly (e.g. behind) interchangeable graphic module 200 and user input may be sensed by the touch sensor device 102 through the interchangeable graphic module 200.

The code input device 104 may receive or obtain the graphic code 204, which may then be communicated to processor 106. Code 204 may allow processor 106 to obtain or identify configuration information for the particular interchangeable graphic module 200. The configuration information may include one or more of a location, a shape, or a size of a graphical element, a machine function or other input parameter to be associated with the graphical element, computer instructions or computer executable code, or any other suitable information. The configuration information may then allow user input system 100 to configure a soft-key that corresponds to the one or more graphical elements marked on the interchangeable graphic module 200.

Configuration information may be stored or retrieved from any suitable location. In an embodiment, configuration information may be stored in memory of the processor 106 of the input system 100. In an embodiment, configuration information may be stored in memory 107 of user input system 100. In an embodiment, configuration information may be stored in the interchangeable graphic module 200. In an embodiment, configuration information may be encoded in the code 204 at the interchangeable graphic module 200. Furthermore, in some embodiments, only part of the configuration information for a given interchangeable graphic module 200 may be stored in a given location. In use, configuration information may be retrieved or obtained by the processor 106 from one or more locations.

In some embodiments, the graphic code 204 may be as simple as a string of one or more alpha-numeric or other characters. In an embodiment, the input system 100 receives at the code input device 104 and associates the graphic code 204 with a predetermined interchangeable graphic module configuration (e.g. graphic layout of buttons, functions, etc.) already stored at the input system 100. In another embodiment, the input system 100 receives the graphic code 204 and then attempts to obtain some or all configuration information from a source external to the input system 100. The configuration information may be stored at an external database or other storage medium, and may be accessed by the input system 100 over a wired or wireless communication path. Examples include but are not limited to Ethernet, Wi-Fi, and cellular connections.

In some embodiments, at least some configuration information is stored at the interchangeable graphic module 200 and is received at the code input device 104 of the input system 100. As previously mentioned, in an embodiment, configuration information is encoded in the graphic code 204. Configuration information may comprise a set of data that can be read directly in a predetermined format by the processor 106 and which defines the graphical layout 202 of the interchangeable graphic module 200, including for each soft-key. In an embodiment, the data completely defines the graphical layout 202 for every soft-key.

In embodiments where the configuration information includes a set of data that is readable by the processor 106 to define the graphical layout 202, the configuration information may include one or more of the following types of information or data. In an embodiment, configuration information includes a shape of a button graphic as well as coordinates or other positional information for the button graphic. An example is “square, x1, y1, x2, y2”), which represents that a graphic element is a square having opposing corners with coordinates x1,y1 and x2,y2, respectively, indicating where the square is positioned on sensor panel 102.

In an embodiment, configuration information includes selection indices that are related to the end use of the machine. A selection index is a way to link the business logic of a machine (e.g. a dispenser, etc.) to the user interface of user input system 100. A configured soft-key has its geometry defined such that when it is pressed, the touch event is identified as “button X pressed”. For example, software running on electronic processor of user input system 100 may have a single function “CheckSelection” that evaluates the configuration data of soft-key “button X”. The evaluation of the configuration data for “button X” determines that “button X” is assigned to “select cup size as small”. Thus the user input system 100 evaluates the configuration data relating to a specific soft-key to determine its function or selection. Other soft-keys may be associated with configuration data relating to other selection criteria, such as “select target beverage as tea” or “select dispensed liquid as cream”. In a different embodiment, software running on electronic processor of user input system 100 already includes the functions of each soft-key so that the software does not need to evaluate the configuration data for a given soft-key when it is pressed. The software may simply perform the function corresponding to the soft-key (e.g. “SmallButtonPressed”, “CreamButtonPressed”, “IcedCoffeeButtonPressed”, etc.) rather than performing the “CheckSelection” function to evaluate the configuration data for the given soft-key.

In an embodiment, a liquid dispenser may provide for a selection for one or more of a beverage type, a cup size, a product to be dispensed, a shot count, and a recipe multiplier. The product may be the beverage itself, one or more products to be added to a beverage, such as milk, cream, sugar, or flavouring, or a combination thereof. A shot count is the number of shots or unit doses of a product, for example 2 shots of sugar or 1 shot of cream. A recipe multiplier is value for scaling the amount of beverage or product to be dispensed (e.g. x1/4, x1/2, x2, x3, x4. etc.). Selection criteria such as those just described may be included in selection indices linking soft-keys to functions of the dispensing machine.

In an embodiment, configuration information includes a reference to one of a plurality of a pre-existing “onClick” or “buttonDown” functions known to the user input system 100, where each function determines a beverage type, a cup size, and a liquid product. An “onClick” function relates to a press and release touch sensor event, for example where a soft-key is touched and immediately released. In contrast, a “buttonDown” function relates to a press and hold touch sensor event, for example where a soft-key is touched and held for a minimum period of time. These different functions may allow for different functionality based on the type of input received at a soft-key.

In an embodiment, configuration information includes selection indices having a list of references to pre-existing functions known to the user input system 100. The pre-existing functions act on the selection indices and may be executed in the order they are listed. For example, software running on a processor of the input system 100 may have functions such as “checkSelection”, “attemptDispense”, and “clearSelection”. These functions may be called from elsewhere in the software based on the evaluation of an “if-else ladder” code segment. These functions are examples of “onClick” functions specific to the business logic of a dispensing machine based on a beverage recipe. Additionally, a soft-key may be configured as follows [Selection {Any Beverage, Any Product, x1, Small}; Functions {“checkSelection”, “attemptDispense”}]. In this example, when the above configured soft-key (Single Small) is pressed, the configuration data is parsed and the if-else ladder will first call “checkSelection” to evaluate {Any, Any, x1, Small}. The if-else ladder will then call “attemptDispense”, which determines if the current button press has completely selected a recipe target. In this case, Product and Beverage must be preselected for a dispense action to occur.

In an embodiment, configuration information includes selection indices and source code (e.g. one or more scripts, etc.) that is processed by a processor on user input system 100. The source code includes code that relates to the selection and dispensing functions of the dispensing machine, which may be triggered in response to user input. In an embodiment, configuration information includes computer executable instructions retrievable from an external storage medium or other source (e.g. Ethernet, Wi-Fi, etc.).

In some embodiments, the configuration information includes process values, which indicate types and volumes of product to be dispensed. An example process value is 15 milliliters of product (e.g. cream, milk, etc.). Process values may include or be in the form of a recipe table containing elements of a beverage recipe, such as beverage types, cup sizes, or additive products. These process values may match the selection indices of the soft-key. In an example, the visual marking on an interchangeable graphic module is “Single Small”. The selection indices are {Any Beverage, Any Product, x1, Small }, and the process value for {Coffee, Cream, x1, Small } is 15 milliliters. Thus the selection indices are related to the visual markings on the interchangeable graphic module, and the process values are related to the selection indices.

In an embodiment, the configuration information includes scripts in a programming language that are parsed and processed by software running on the processor, referenced by the soft-buttons (e.g. triggered in response to input at a soft-key), and launched by the processor. In an embodiment, the configuration information includes machine executable instructions (e.g. compiled) as functions, referenced by the soft-buttons and executed by the processor.

In some embodiments, the graphic code 104, which may include configuration information, may be received at the user input system 100 in a compressed format and then decompressed by the user input system 100. In some embodiments, the graphic code may be received at the user input system 100 in an encrypted format and then decrypted by the input system 100.

In an embodiment, configuration information encoded in the graphic code 204 is related to a subset of instructions already stored in the processor 106 or accessible by the processor 106. Based on this configuration information, the processor 106 retrieves and executes the subset of instructions in order to identify or determine a graphical layout of the interchangeable graphic module 200 that is engaged with the input system 100.

In addition, one or more specific functions may be mapped to the soft-keys configured for the touch sensor device 102. This may be performed by the processor 106. For example, when the touch sensor device 102 indicates a touch at a first soft-key associated with a coffee button imprinted on the interchangeable graphic module 200, the processor 106 can cause the generation of an output signal to dispense coffee. When the touch sensor device 102 indicates a touch at a second soft-key associated with a tea button imprinted on the interchangeable graphic module 200, the processor 106 can generate an output signal to dispense tea. Output signals may be communicated by input system 100 through communications subsystem 105.

In use, one interchangeable graphic module 200 may be disengaged and removed from the user input system 100 and replaced with another interchangeable graphic module 200. The processor 106 may receive the graphic code 204 of the new interchangeable graphic module 200. One or more soft-keys may then be configured and mapped based on configuration information associated with the new graphic code 204.

The touch sensor device 102 may comprise any suitable touch sensing technology. In some embodiments, touch sensor device 102 may comprise a transparent sensor panel of any suitable type, including the capacitive type or the resistive type. In an embodiment, the transparent sensor panel may comprise a transparent film. When touch sensor device 102 is transparent, the interchangeable graphic module 200 may be receivable behind the touch sensor device 102. The one or more graphical elements of the interchangeable graphic module 200 may be viewable (e.g. by a user) through the transparent film of the touch sensor device 102. When the user touches the touch sensor device 102 at a soft-key corresponding to the location of a graphical element, the touch sensor device 102 may register a user input signal and provide the user input signal to the processor 106.

Again, in other embodiments, the interchangeable graphic module 200 may be mounted in front of the touch sensor device 102 and sensor device 102 may register a user input when the user directly touches a graphical button or text on the interchangeable graphic module 200.

The interchangeable graphic module 200 may be constructed from any suitable material or materials, including one or more of paper, cardboard, or plastic. Thus, the material cost of the interchangeable graphic module 200 can be very low.

The graphic code 204 can be any means for encoding configuration information relating to the graphical layout 202 of the interchangeable graphic module 200. The code 204 may be stored in a memory or other storage medium of the interchangeable graphic module 200, for example in an integrated circuit or in a magnetic stripe. In some embodiments, user input system 100 may obtain code 204 wirelessly from interchangeable graphic module 200. In this regard, code input device 104 may comprise a wireless interface device (not shown) configured to obtain or receive the code 204 from the interchangeable graphic module 200 over a wireless radio frequency signal.

In an embodiment, the graphic code 204 may be contained in a radio-frequency identification (RFID) chip embedded in, or affixed to, the material of the interchangeable graphic module 200, and the code input device 104 may comprise an RFID reader. In operation, when the interchangeable graphic module 200 is engaged with the input system 100, the RFID reader 104 wirelessly reads the code associated with the graphical layout 202 from the RFID chip 204 and transmits the code to the processor 106. This reading operation may be performed automatically in response to the engagement of the interchangeable graphic module 200 with the input system 100.

In another embodiment, graphic code 204 may be in the form of an optical machine-readable representation marked on the module 200. For example, code 204 may be provided in a quick response (QR) code, barcode, or any other visual marking on the interchangeable graphic module 200. The code input device 104 may comprise an optical scanner or optical sensor for reading the code marking on the graphic module 200. In operation, when the interchangeable graphic module 200 is engaged with the user input system 100, the optical scanner 104 may optically scan the code associated with the graphical layout 202 from the QR code or barcode 204 and transmit the code to the processor 106. This operation may also be performed automatically in response to engagement of the interchangeable graphic module 200 with the user input system 100.

In another embodiment, the code input device 104 may comprise a physical connector configured to engage the interchangeable graphic module 200 and to receive the code 204 from the interchangeable graphic module 200. The physical connector may be any suitable type, such as an electrical contact, electrical pin, or magnetic stripe reader.

When an interchangeable graphic module 200 is received by the module interface of user input system 100, the region of module 200 bearing or containing the graphic code 204 may align with code input device 104 of the system 100. For example, in an embodiment where the code is marked on the module 200, the marked code may align with an optical scanning device of the code input device 104 such that the scanning device can scan the marked code. As another example, in an embodiment where the code 204 is stored in a memory on module 200, the memory or an interface for the memory may align with the code input device 104 of the user input system so that the code input device may obtain the code from the memory of the module 200.

In another more simplistic embodiment, the graphic code 204 may be in the form of one or more alpha-numeric characters visually marked on the module (e.g. a serial number) and the code input device 104 may include a key pad or other user input device for manual user input of the code 104. In this manual operation, a user reads the alpha-numeric code from the interchangeable graphic module 200 or elsewhere, and manually inputs the code into the key pad. The processor 106 may then receive the code from the key pad. The code entry may be performed before or after the interchangeable graphic module 200 is engaged with the user input system 100.

In some embodiments, the processor may be configured to configure and map the soft-key automatically in response to the user input system 100 being powered up and the interchangeable graphic module 200 being engaged with the user input system.

Once the one or more soft-keys are configured for the touch sensor device 102 and the soft-keys are mapped to particular functions or selections, input may be received at the soft-keys. The user input system 100 may thus receive input at the soft-key of the touch sensor device 102, and generate a machine function output signal in response to the received input where the machine function output signal corresponds to the function of the graphical element. For example, if input is received at a soft-key corresponding to a graphical element representing the dispensing of coffee, the user input system 100 may generate a machine function output signal for dispensing coffee. This signal may be communicated to beverage dispensing machine through communications subsystem 105 of system 100. It is also contemplated that a generated output signal may comprise or represent information other than a machine function. A generated output signal may indicate any input parameter, such as an indication that a beverage is to have a particular size (e.g. small) without necessarily instructing the dispensing of the beverage.

Although FIGS. 2A and 2B show touch sensor device 102, code input device 104, communications subsystem 105, and memory 107 of user input system 100 are shown connected to processor 106, this is not meant to be limiting. Communications between two or more various elements of user input system 100 may be through one or more internal buses (not shown) in one embodiment. Other forms of communication are also possible.

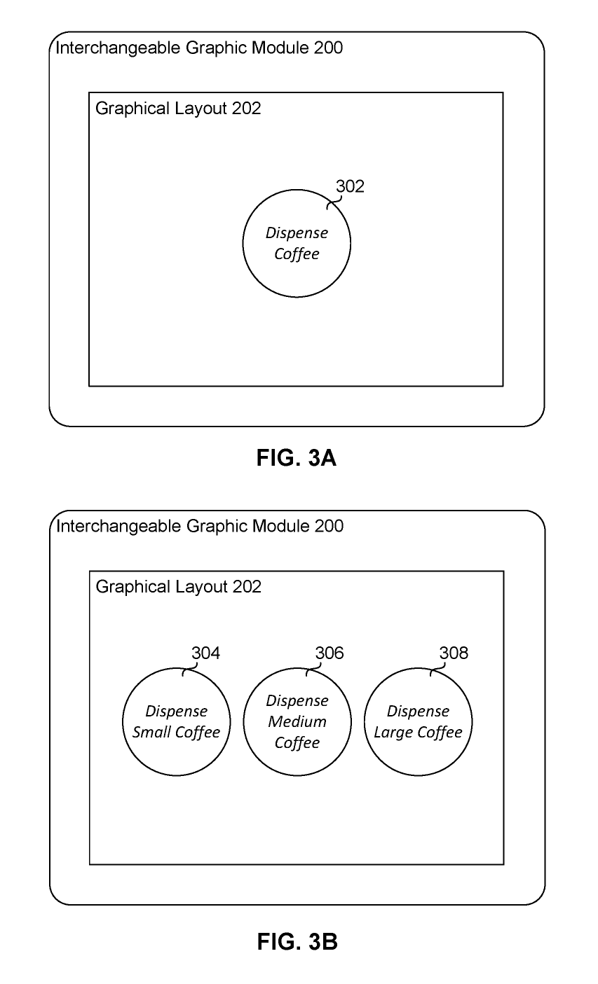

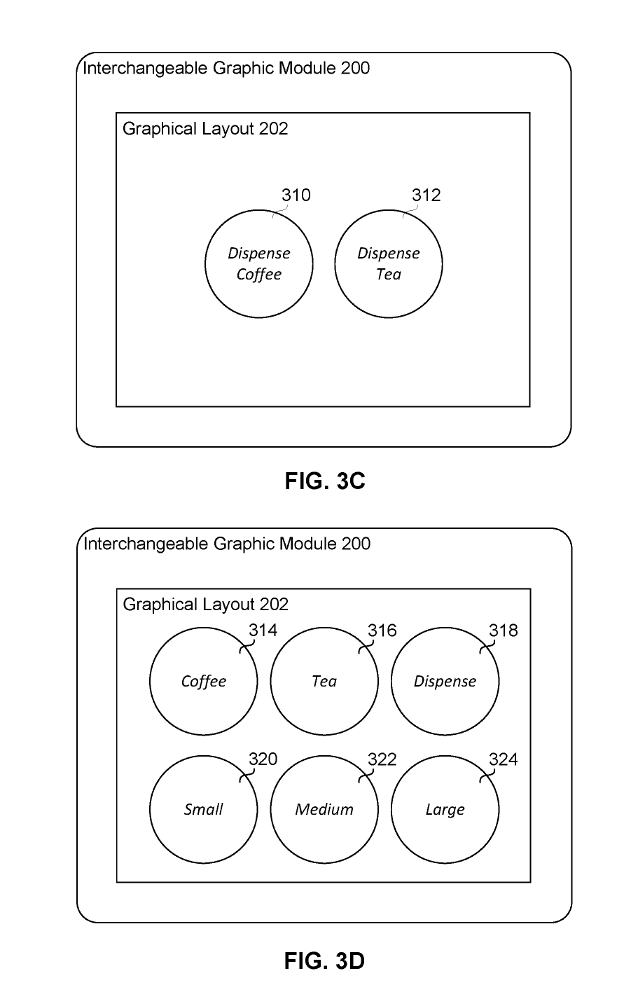

FIGS. 3A-3D show some example variations of the interchangeable graphic module 200. In FIG. 3A, the graphical layout 202 comprises a single graphical element 302 marking in the form of a button graphic for dispensing coffee. When the processor 106 receives the configuration information in the graphic code 204, a soft-key is configured for the touch sensor device 102, and the processor 106 maps the soft-key to a dispense coffee function. Processor 106 is then configured to generate a machine function output signal to dispense coffee when the touch sensor device 102 receives input (e.g. detects a touch) at the soft-key.

In FIG. 3B, the graphical layout 202 comprises three graphical elements 304, 306, 308 marked on interchangeable graphic module 200 in the form of button graphics for dispensing different sizes of coffee. When the processor 106 receives the configuration information in the graphic code 204, the processor 106 configures three soft-keys for the touch sensor device 102. Each soft-key may be located, sized and/or shaped to correspond to the position, size and/or shape of each graphical element on the interchangeable graphic module 200. The processor 106 may map a function to each soft-key. In addition, processor 106 may be configured to generate a machine function output in response to input at each soft-key.

In FIG. 3C, the graphical layout 202 comprises two graphical elements 310, 312 in the form of two button graphics for dispensing different types of beverage.

In FIG. 3D, the graphical layout 202 comprises six graphical elements 314, 316, 318, 320, 322 and 324 in the form of six button graphics associated with different functionalities. The graphical elements include types of beverage, such as coffee or tea, and sizes of beverage, as well as a dispense button. The processor 106 may configure soft-keys for the touch sensor device 102 for each of the graphical elements based on the code 204 of the interchangeable graphic module 200. When the touch sensor device 102 detects a touch on the coffee soft-key, the processor 106 may register the selection of coffee, but may not dispense coffee. When the touch sensor device 102 next detects a touch on the small soft-key, the processor may register the selection of a small size. When the touch sensor device 102 next detects a touch at the dispense soft-key, the processor 106 may then generate a machine function output signal based on the three inputs indicating that a small coffee is to be dispensed. In another embodiment, the processor 106 may generate a machine function output signal for one or more of the inputs received at the touch sensor device 102. For example, a signal may be generated for each of input, namely “coffee”, “small”, and “dispense”. These signals may be communicated to a beverage dispensing machine.

By providing the user input system 100 with different interchangeable graphic modules 200, the input system 100 may be flexibly configured for various different modes of operation and various commercial applications. Therefore in some embodiments, the user input system 100 has the functionality of soft-keys, without the complexity, cost, or fragility of conventional touchscreen input systems that require an electronic display.

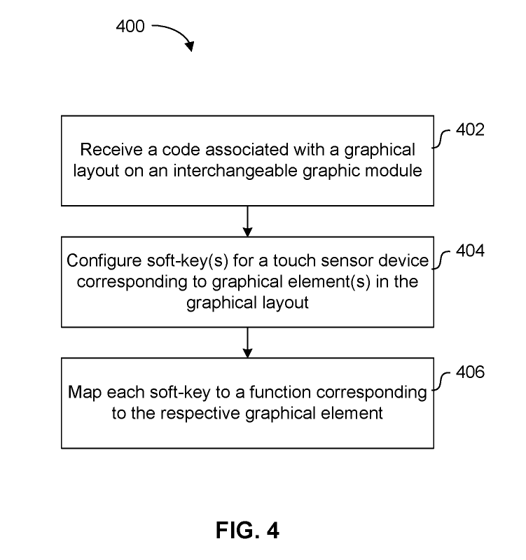

FIG. 4 shows a flowchart comprising steps in a method for configuring the input system 100 according to an embodiment of the present disclosure. One or more steps in method 400 may be performed by the processor 106. The method 400 comprises, at block 402, receiving a graphic code associated with a graphical layout on an interchangeable graphic module.

The method proceeds to block 404, where one or more soft-keys for a touch sensor device are configured. The configured soft-keys correspond to the graphical elements in the graphical layout of the interchangeable graphic module. For example, the processor 106 may configure a soft-key to correspond to each graphical element (e.g. button graphic, etc.) in the graphical layout.

The method proceeds to block 406, where each soft-key may be mapped to a function corresponding to its respective graphical element. For example, the processor 106 may map a soft-key corresponding to a “coffee” graphical element to a ‘select coffee’ function or a ‘dispense coffee’ function.

In some embodiments, the method 400 may also comprise receiving computer-readable instructions from the graphic code 204. For example, the graphic code 204 may be an RFID chip having an internal memory for storing computer-readable instructions for identifying the variation (e.g. graphical layout) of the interchangeable graphic module 200 and configuration information related to the instructions. The processor 106 may use the computer-readable instructions from the RFID chip to supplement the instructions already stored on the processor 106 or accessible to the processor 106.

In operation, the processor 106 may load the computer-readable instructions from the graphic code 204 into the local memory of the processor 106 or memory 107 of system 100. The processor may also read the configuration information from the graphic code 204. The configuration information may be related to the newly-loaded instructions, rather than the instructions previously stored on or accessible to the processor 106. Therefore if new interchangeable graphic modules 200 are produced on a date after the firmware date of the processor 106, then the firmware of the processor 106 can be updated to be compatible with the new interchangeable graphic modules 200 according to this embodiment. Using the newly-loaded instructions, the processor 106 may identify a new interchangeable graphic module 200 in order to configure soft-keys on the touch sensor device 102 corresponding to the graphical layout 202 and create soft-key mappings to the functions described in graphical layout 202.

In some embodiments, the configuration information, which may include programming code or computer-readable instructions, may additionally or alternatively include one or more of recipe information, default button selection information, or alternate languages. In embodiments that have an electronic device for displaying information (e.g. a display screen, etc.), language information in the configuration information may allow input system 100 to display information in a same language used on the interchangeable graphic module.

In an embodiment, the method 400 is executed by the processor 106 at the machine boot up of the input system 100. In another embodiment, the method 400 is executed by the processor 106 during normal operation of the input system 100. In this case, the code input device 104 may generate a hardware interrupt to cause the processor 106 to perform the method 400.

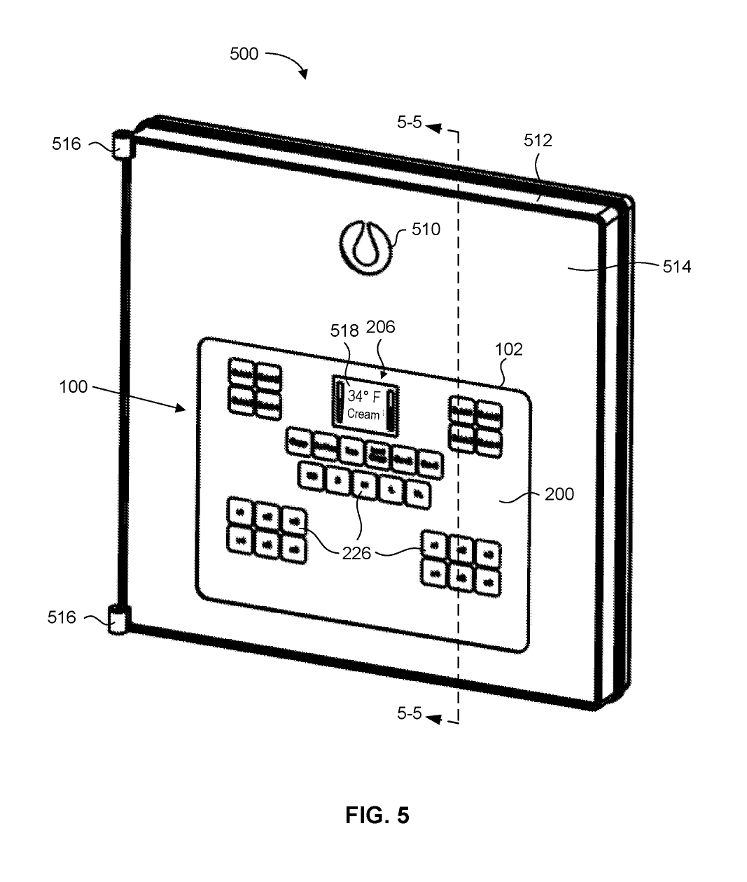

FIG. 5 shows a perspective view of the front of a door 500 of a refrigerated dispensing machine (not shown) according to an embodiment. Door 500 comprises a housing 512, which receives part or all of the user input system 100. Door 500 may be pivotally connected to the dispensing machine by way of one or more hinges 516. Housing 512 comprises a front panel 514, which may be secured to the front of housing 512. In an embodiment, front panel 514 is secured to housing 512 with adhesive. Front panel 514 comprises a transparent portion, or alternatively a cutout, in the region in which touch sensor device 102 is located. In an embodiment, touch sensor device 102 is laminated to front panel 514.

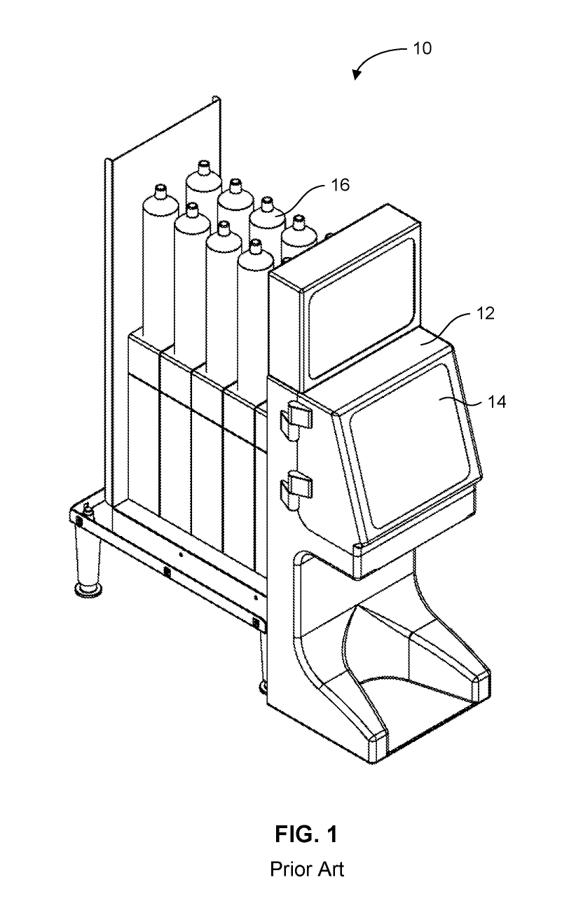

The user input system 100 is shown with an interchangeable graphic module 200 engaged with the user input system 100 and positioned behind a touch sensor device 102. The interchangeable graphic module 200 is shown with various example graphical elements 226. The touch sensor device 102 and interchangeable graphic module 200 are positioned at the front panel 514 of housing 512. Thus in this embodiment, housing 512 serves as a housing for at least part of the user input system 100 (e.g. electronics, interchangeable graphic module, etc.) and also as a door for a dispensing machine. An example of a door of a dispensing machine is shown in FIG. 1, where door 12 is pivotally or hingedly connected to the frame or body of the dispensing machine.

In the embodiment of FIG. 5, the user input system 100 further comprises an optional small electronic display 518, such as an LCD display, that may be used for displaying system information to a user. In this example, the display 518 is showing a temperature of 34 degrees F. The display 518 may be located behind both the touch sensor device 102 and the interchangeable graphic module 200. Accordingly, the interchangeable graphic module 200 may have a cutout 206 for viewing the display 518 through the interchangeable graphic module 200. The user input system 100 may also comprise an optional machine status indicator 510 for displaying additional system information to the user. Indicator 510 may comprise one or more light emitting diodes (LEDs) or other lights for conveying information.

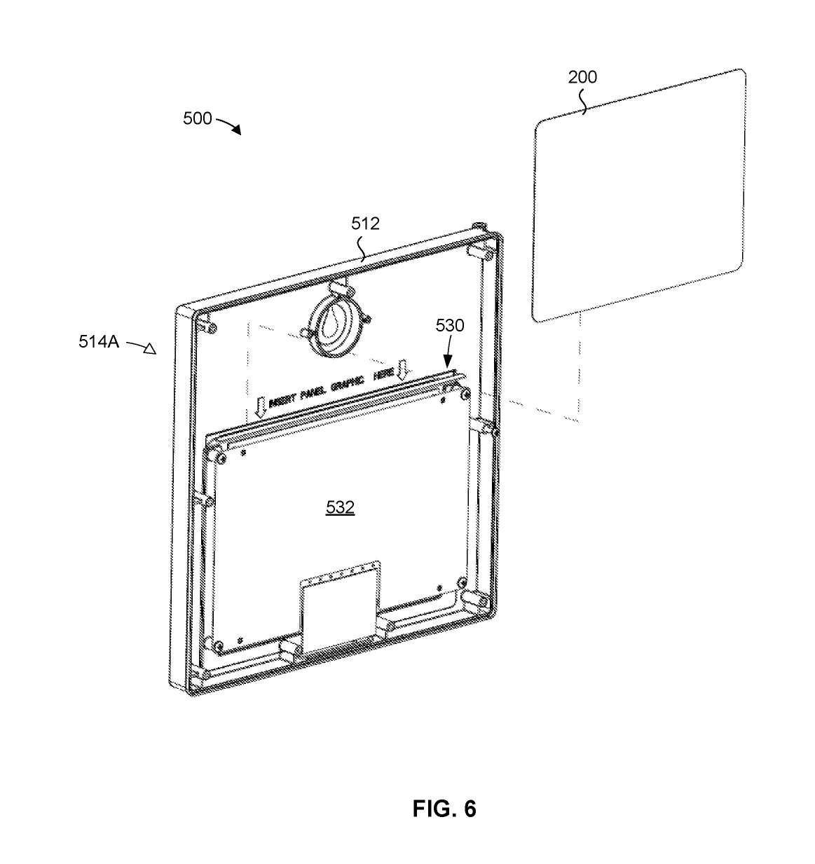

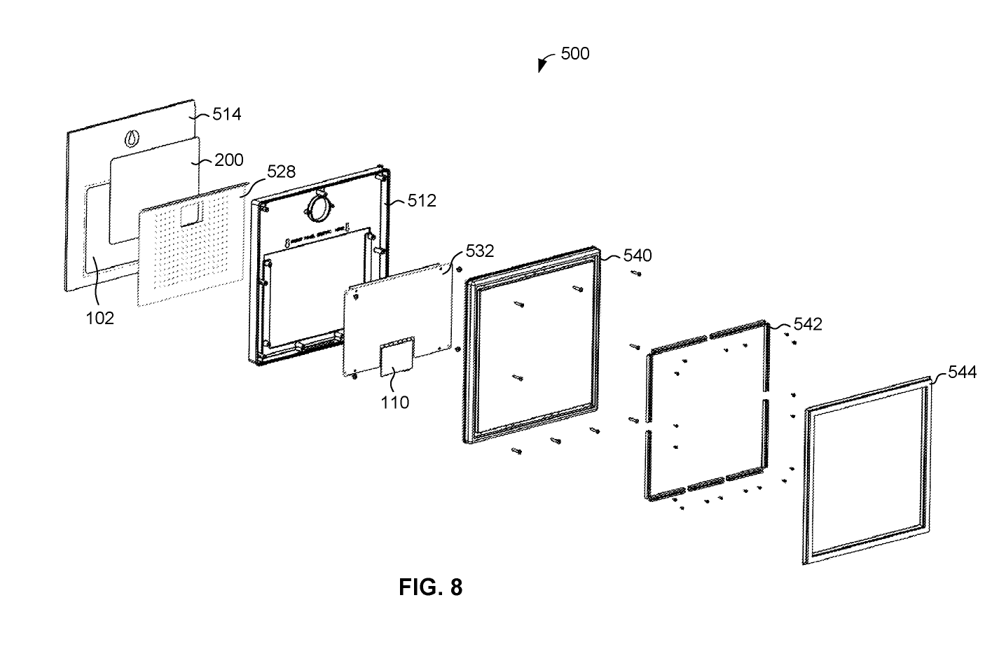

FIG. 6 shows a rear perspective view of the door 500 of FIG. 5 without a back panel. Although not shown, the front panel side of housing 512 is indicated by arrow 514A. A back panel may be removed to allow access to the inside of housing 512, including to access a mounting interface for receiving an interchangeable graphic module 200. In this example, a mounting device (shown in FIG. 8) located between housing 512 and electronics support 532 defines a slot 530 behind the touch sensor device 102 for receiving the interchangeable graphic module 200. In this regard, interchangeable graphic module 200 is receivable in an overlapping relationship with touch sensor device 102. An interchangeable graphic module 200 received by the mounting interface would lie in a plane that is approximately parallel to a plane defined by the touch sensor device 102.

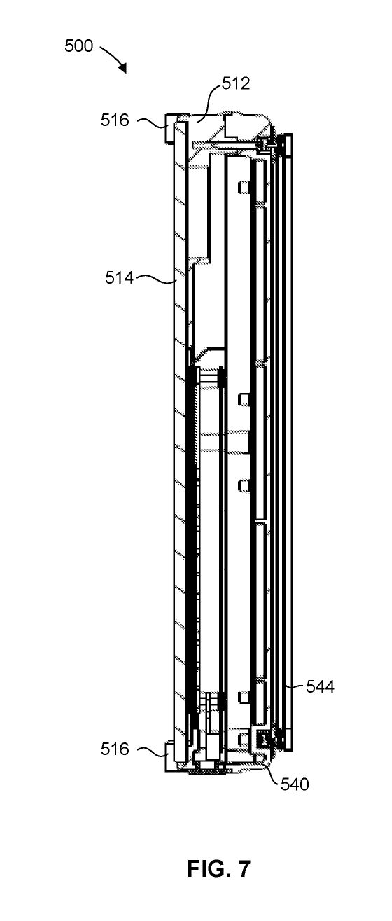

FIG. 7 shows a cross-sectional side view of the input system 100 of FIG. 5 along line 5-5 shown in FIG. 5.

FIG. 8 shows an exploded view of an embodiment of door 500. Mounting device 528 receives interchangeable graphic module 200 within slot 530 defined between mounting device 528 and the touch sensor device 102. In this embodiment, mounting device 528 defines a cutout for the electronic display 518 shown in FIG. 5 as well as a plurality of small mask holes, which may be used for back lighting of the interchangeable graphic module 200. Door 500 further includes an insulated housing back panel 540, a removable magnetic door gasket 544, and mounting tracks 542 for securing door gasket 544 to the back panel 540. In addition, some or all electronics 110 of user input system 100 may be positioned at electronics support 532.

To engage or disengage an interchangeable graphic module 200 from user input system 100 within door 500, insulated housing back panel 540 may be removed to expose slot 530.

Although in the embodiments of FIGS. 5-8 the user input system 100 is housed within a door of a dispenser machine, this is not limiting. The user input system 100 according to the present disclosure can be adapted to be located in other parts of any machine, system, or other apparatus. In addition, the user input system 100 may be configured for use with machines and systems other than beverage dispensing machines.

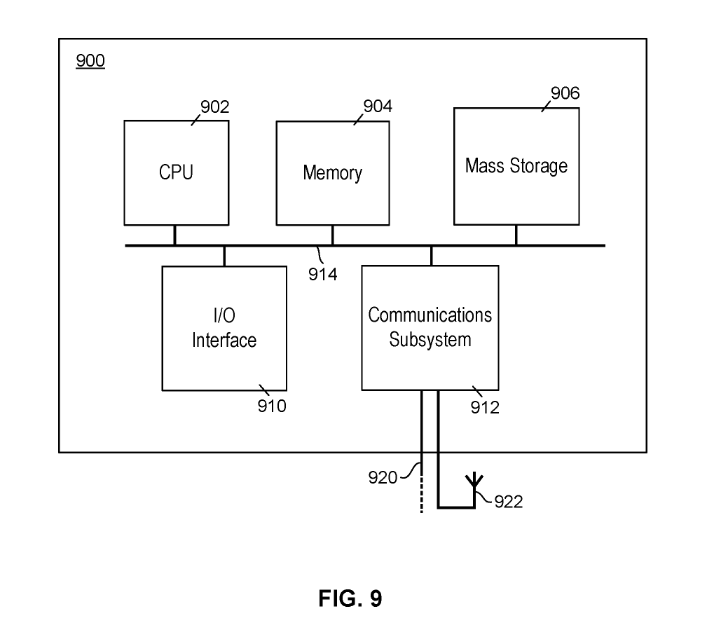

FIG. 9 is a block diagram of an example electronic device 900 that may be used in implementing one or more aspects or components of an embodiment according to the present disclosure.

The electronic device 900 may include one or more of a central processing unit (CPU) 902, memory 904, a mass storage device 906, an input/output (I/O) interface 910, and a communications subsystem 912. One or more of the components or subsystems of electronic device 900 may be interconnected by way of one or more buses 914 or in any other suitable manner.

The bus 914 may be one or more of any type of several bus architectures including a memory bus, storage bus, memory controller bus, peripheral bus, or the like. The CPU 902 may comprise any type of electronic data processor. The memory 904 may comprise any type of system memory such as dynamic random access memory (DRAM), static random access memory (SRAM), synchronous DRAM (SDRAM), read-only memory (ROM), a combination thereof, or the like. In an embodiment, the memory may include ROM for use at boot-up, and DRAM for program and data storage for use while executing programs.

The mass storage device 906 may comprise any type of storage device configured to store data, programs, and other information and to make the data, programs, and other information accessible via the bus 914. The mass storage device 906 may comprise one or more of a solid state drive, hard disk drive, a magnetic disk drive, an optical disk drive, or the like. In some embodiments, data, programs, or other information may be stored remotely, for example in the “cloud”. Electronic device 900 may send or receive information to the remote storage in any suitable way, including via communications subsystem 912 over a network or other data communication medium.

The I/O interface 910 may provide interfaces to couple one or more other devices (not shown) to the electronic device 900. The other devices may include but are not limited to one or more of a food or beverage dispensing machine, a touch sensor device, a code input device, an electronic display, an indicator light (e.g. light emitting diode), a speaker, a microphone, and a sensor. Furthermore, additional or fewer interfaces may be utilized. For example, one or more serial interfaces such as Universal Serial Bus (USB) (not shown) may be provided.

A communications subsystem 912 may be provided for one or both of transmitting and receiving signals. Communications subsystems may include any component or collection of components for enabling communications over one or more wired and wireless interfaces. These interfaces may include but are not limited to USB, Ethernet, high-definition multimedia interface (HDMI), Firewire (e.g. IEEE 1394), Thunderbolt™, WiFi™ (e.g. IEEE 802.11), WMAX (e.g. IEEE 802.16), Bluetooth™, or Near-field communications (NFC), as well as GPRS, UMTS, LTE, LTE-A, dedicated short range communication (DSRC), and IEEE 802.11. Communication subsystem 912 may include one or more ports or other components 920 for one or more wired connections. Additionally or alternatively, communication subsystem 912 may include one or more of a transmitter (not shown), a receiver (not shown), and an antenna element 920.

The electronic device 900 of FIG. 9 is merely an example and is not meant to be limiting. Various embodiments may utilize some or all of the components shown or described. Some embodiments may use other components not shown or described but known to persons skilled in the art.

In the preceding description, for purposes of explanation, numerous details are set forth in order to provide a thorough understanding of the embodiments. However, it will be apparent to one skilled in the art that these specific details are not required. In other instances, well-known electrical structures and circuits are shown in block diagram form in order not to obscure the understanding. One or more components or features of the present disclosure may be implemented in software, hardware circuitry, firmware, or some combination thereof.

Embodiments of the disclosure can be represented as a computer program product stored in a machine-readable medium (also referred to as a computer-readable medium, a processor-readable medium, or a computer usable medium having a computer-readable program code embodied therein). The machine-readable medium can be any suitable tangible, non-transitory medium, including magnetic, optical, or electrical storage medium including a diskette, compact disk read only memory (CD-ROM), memory device (volatile or non-volatile), or similar storage mechanism. The machine-readable medium can contain various sets of instructions, code sequences, configuration information, or other data, which, when executed, cause a processor to perform steps in a method according to an embodiment of the disclosure. Those of ordinary skill in the art will appreciate that other instructions and operations necessary to implement the described implementations can also be stored on the machine-readable medium. The instructions stored on the machine-readable medium can be executed by a processor or other suitable processing device, and can interface with circuitry to perform the described tasks.

The structure, features, accessories, and alternatives of specific embodiments described herein and shown in the Figures are intended to apply generally to all of the teachings of the present disclosure, including to all of the embodiments described and illustrated herein, insofar as they are compatible. In other words, the structure, features, accessories, and alternatives of a specific embodiment are not intended to be limited to only that specific embodiment unless so indicated.

In addition, the steps and the ordering of the steps of methods described herein are not meant to be limiting. Methods comprising different steps, different number of steps, and/or different ordering of steps are also contemplated.

The above-described embodiments are intended to be examples only. Alterations, modifications and variations can be effected to the particular embodiments by those of skill in the art. The scope of the claims should not be limited by the particular embodiments set forth herein, but should be construed in a manner consistent with the specification as a whole.

What is claimed is:

1. A method for configuring a user input system, the method comprising:
receiving a code at a code input device of the user input system, the code associated with a graphical layout of an interchangeable graphic module releasably engaged with the user input system, and the graphical layout comprising a graphical element visually marked on the interchangeable graphic module and corresponding to a machine function;
automatically configuring by a processor of the user input system, based on the graphical layout associated with the received code, a soft-key for a touch sensor device corresponding to the graphical element; and
mapping the soft-key to the machine function corresponding to the graphical element.

2. The method of claim 1, wherein the automatically configuring and mapping the soft-key is based on configuration information associated with the received code, the configuration information comprising information indicating at least one of: a location, a shape, or a size of the graphical element, or a machine function associated with the graphical element.

3. The method of claim 2, further comprising retrieving at least part of the configuration information from a memory of the user input system.

4. The method of claim 2, further comprising obtaining at least part of the configuration information from the interchangeable graphic module.

5. The method of claim 1, further comprising:
receiving, at the user input system, computer readable instructions associated with the code from the interchangeable graphic module,
wherein at least one of the automatically configuring the soft-key and the mapping the soft-key involves executing the received computer readable instructions by the processor of the user input system.

6. The method of claim 1, wherein the receiving the code comprises receiving the code from the interchangeable graphic module over a wireless radio frequency signal.

7. The method of claim 1, wherein the receiving the code comprises reading a graphical representation of the code from the interchangeable graphic module using an optical scanning device of the code input device.

8. The method of claim 1, wherein the configuring and mapping the soft-key is performed automatically in response to the user input system being powered up and the interchangeable graphic module being engaged with the user input system.

9. The method of claim 1, further comprising:
receiving input at the soft-key of the touch sensor device; and
generating a machine function output signal in response to the received input, the machine function output signal corresponding to the machine function that corresponds to the graphical element.

10. The method of claim 1, wherein the graphical layout of the interchangeable graphic module further comprises a second graphical element visually marked on the interchangeable graphic module and corresponding to a second machine function, the method further comprising:
automatically configuring by the processor, based on the graphical layout associated with the received code, a second soft-key for the touch sensor device corresponding to the second graphical element;
mapping the second soft-key to the second machine function corresponding to the second graphical element;
receiving a first input at the soft-key;
receiving a second input at the second soft-key;
generating a machine function output signal in response to the received first and second inputs, the machine function output signal corresponding to the two machine functions of the two graphical elements.

11. The method of claim 1, wherein the interchangeable graphic module is positioned in an overlapping relationship with the touch sensor device when the interchangeable graphic module is engaged with the user input system.

12. A user input system comprising:
an interface for receiving an interchangeable graphic module having a code associated with a graphical layout of the module, the graphical layout comprising a graphical element visually marked on the interchangeable graphic module and corresponding to a machine function;
a touch sensor device;
a code input device; and
a processor in communication with the touch sensor device and the code input device, the processor configured to:
receive, via the code input device, the code associated with the graphical layout of the interchangeable graphic module;
configure, based on the graphical layout associated with the received code, a soft-key for the touch sensor device corresponding to the graphical element; and
map the soft-key to the machine function corresponding to the graphical element.

13. The user input system of claim 12, wherein the processor is configured to configure the soft-key and map the soft-key based on configuration information associated with the received code, the configuration information comprising information indicating at least one of: a location, a shape, or a size of the graphical element, or a machine function associated with the graphical element.

14. The user input system of claim 13, further comprising a memory, wherein the processor is configured to retrieve at least part of the configuration information from the memory.

15. The user input system of claim 13, wherein the processor is configured to obtain at least part of the configuration information from the interchangeable graphic module.

16. The user input system of claim 12, further configured to:
receive computer readable instructions associated with the code from the interchangeable graphic module,
wherein the processor is further configured to at least one of configure the soft-key and map the soft-key based on the execution of the received computer readable instructions by the processor.

17. The user input system of claim 12, wherein the code input device comprises a wireless interface device, and wherein the user input system is configured to receive the code from the interchangeable graphic module over a wireless radio frequency signal using the wireless interface device.

18. The user input system of claim 12, wherein the code input device comprises an optical scanning device configured to read a graphical representation of the code from the interchangeable graphic module.

19. The user input system of claim 12, wherein the processor is configured to configure and map the soft-key automatically in response to the user input system being powered up and the interchangeable graphic module being engaged with the user input system.

20. The user input system of claim 12, further configured to:
receive input at the soft-key of the touch sensor device; and
generate a machine function output signal in response to the received input, the machine function output signal corresponding to the machine function of the graphical element.

21. The user input system of claim 12, wherein when the graphical layout of the interchangeable graphic module further comprises a second graphical element visually marked on the interchangeable graphic module and corresponding to a second machine function:
the processor is further configured to configure a second soft-key for the touch sensor device corresponding to the second graphical element, and map the second soft-key to the second machine function, and
wherein the user input system is further configured to:
receive a first input at the soft-key;
receive a second input at the second soft-key; and
generate a machine function output signal in response to the received first and second inputs, the machine function output signal corresponding to the two machine functions of the two graphical elements.

22. The user input system of claim 12, wherein the interchangeable graphic module is receivable by the interface in an overlapping relationship with the touch sensor device.

23. The user input system of claim 22, wherein the touch sensor device comprises a transparent sensor panel, and wherein the interchangeable graphic module is receivable by the interface behind the transparent panel such that the graphical layout is viewable through the transparent sensor panel.

24. The user input system of claim 12, further comprising the interchangeable graphic module.
